(19) United States
(12) Patent Application Publication
(10) Pub. No.: US 2008/0024328 A1
(43) Pub. Date: Jan. 31, 2008

(54) Key expansion apparatus of electronic device

(75) Inventor: Heui-Do Lim, Suwon-si (KR)

Correspondence Address: THE FARRELL LAW FIRM, P.C., 333 EARLE OVINGTON BOULEVARD, SUITE 701, UNIONDALE, NY, 11553, US

(73) Assignee: Samsung Electronics Co., Ltd., Suwon-si (KR)

(21) Appl. No.: 11/732,540

(22) Filed: Apr. 4, 2007

(30) Foreign Application Priority Data
May 22, 2006 (KR) 2006-0045541

(51) Int. Cl. H03M 11/00

(52) U.S. Cl. 341/22; 341/26

(57) ABSTRACT

A key expansion apparatus of an electronic device includes at least one basic key for connecting/disconnecting one of a plurality of first input ports and one of a plurality of second input ports in order to make key input, and at least one additional key for connecting three or more of the first input ports and the second input ports. Accordingly, the key expansion can be achieved using a small number of input ports without additional expense.

### PRIORITY

This application claims priority under 35 U.S.C. §119 to an application filed in the Korean Intellectual Property Office on May 22, 2006 and assigned Serial No. 2006-45541, the contents of which are incorporated herein by reference.

### BACKGROUND OF THE INVENTION

1. Field of the Invention

The present invention relates generally to a key assembly of an electronic device, and in particular, to a key expansion apparatus that can provide for efficient key input using a combination of input ports.

2. Description of the Related Art

Electronic devices use a key matrix to form a large number of key inputs with a small number of input ports. That is, the electronic devices can receive more key inputs than the number of the input ports by changing bit values of the input ports using the key matrix. The key matrix includes a plurality of keys that are arranged in a matrix form and connected to the input ports. Specifically, the keys are arranged in rows and columns, and the number of the keys is equal to that of the input ports of the electronic device. Thus, the key matrix can have as many key inputs as the number of the keys. For example, as illustrated in FIG. 1, when the electronic device has three first input ports and three second input ports, keys are arranged in three rows and three columns. Therefore, the key matrix can have nine key inputs. When a key located in a specific row and a specific column is pressed (or closed) in the key matrix, bit values of input ports corresponding to the pressed key are changed from 0 (logic low, key opened) to 1 (logic high, key closed) in a memory. A central processing unit (CPU) recognizes the changed bit values and performs a corresponding preset operation. For example, when a key[0,2] is pressed in the electronic device with the 3×3 key matrix of FIG. 1, bit values of the first input port Row0 and the second input port Col2 are changed from 0 to 1 and the electronic device performs a corresponding preset operation.

As the electronic devices, particularly wireless communication terminals, have been continually developed, they provide a variety of functions. Therefore, there is a demand for a key input method that can provide more key inputs than ever in order to control a variety of service functions.

To meet the demand, a conventional key expansion apparatus uses a dedicated key input integrated circuit (IC) or a directional device, e.g., a diode as illustrated in FIG. 2. However, the use of the dedicated key input IC or the diode requires additional expense and is inefficient in terms of mounting area. Moreover, such a key expansion apparatus is difficult to implement.

### SUMMARY OF THE INVENTION

An object of the present invention is to substantially solve at least the above problems and/or disadvantages and to provide at least the advantages below. Accordingly, an object of the present invention is to provide a key expansion apparatus that can provide an expanded key input using a combination of input ports in an electronic device.

According to one aspect of the present invention, a key expansion apparatus of an electronic device includes (i) at least one basic key for connecting one of a plurality of first input ports and one of a plurality of second input ports in order for key input; and (ii) at least one additional key for connecting three or more of the plurality of first input ports and the plurality of second input ports.

### BRIEF DESCRIPTION OF THE DRAWINGS

The above and other objects, features and advantages of the present invention will become more apparent from the following detailed description when taken in conjunction with the accompanying drawings in which:

FIG. 1 illustrates a conventional key matrix of an electronic device;

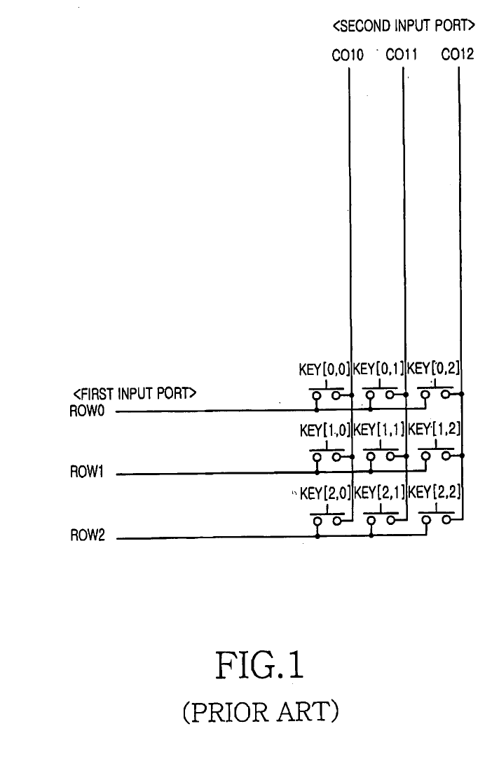

FIG. 2 illustrates a conventional key expansion apparatus of an electronic device;

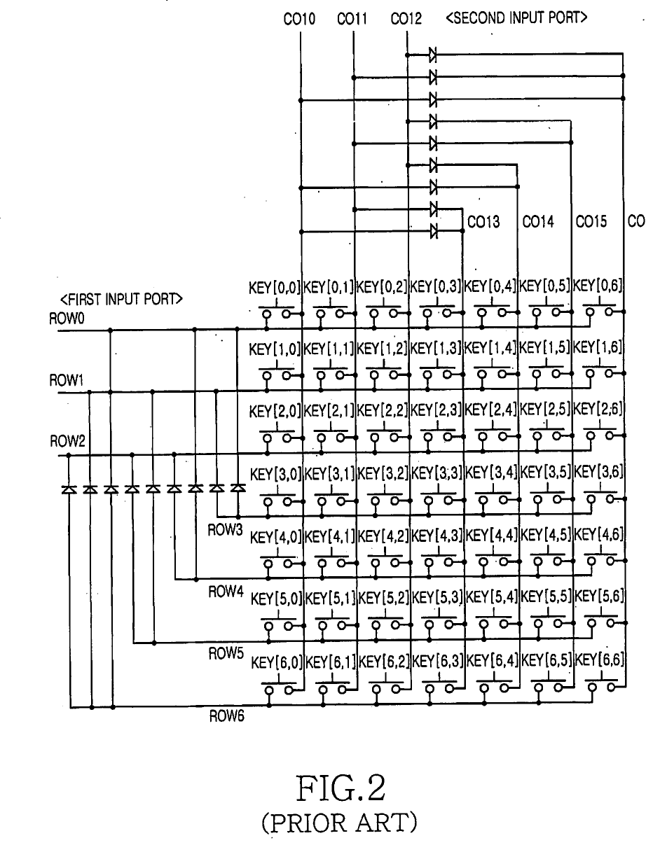

FIG. 3 illustrates a key expansion apparatus of an electronic device according to the present invention; and

FIGS. 4A and 4B illustrate metal domes and printed circuit boards (PCBs) of electronic devices according to the related art and the present invention respectively.

### DETAILED DESCRIPTION OF THE PREFERRED EMBODIMENTS

Preferred embodiments of the present invention will be described herein below with reference to the accompanying drawings. In the following description, well-known functions or constructions are not described in detail since they would obscure the invention in unnecessary detail.

Hereinafter, a key expansion apparatus using a combination of input ports in an electronic device, particularly a wireless communication terminal, will be described in detail.

Although an electronic device having three first input ports and three second input ports will be described, the present invention is not limited to this configuration. That is, the present invention can also be applied to an electronic device having five first input ports and five second input ports, and an electronic device having four first input ports and six second input ports.

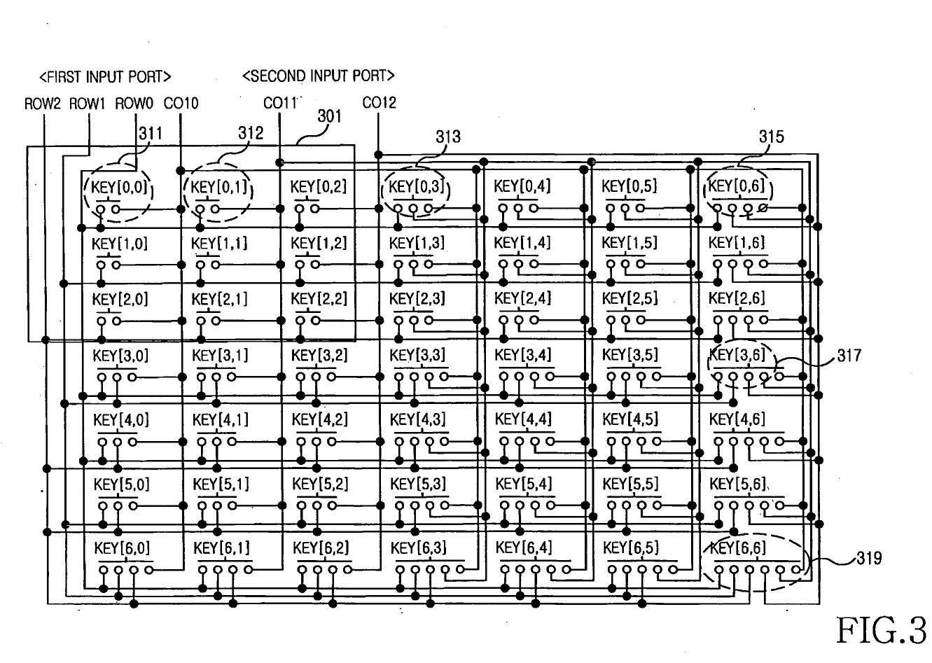

FIG. 3 illustrates a key expansion apparatus of an electronic device according to the present invention.

Referring to FIG. 3, a key matrix according to the present invention has an expanded structure of a 3×3 key matrix that is generally used in an electronic device having three first input ports and three second input ports. Specifically, the key matrix according to the present invention includes the general 3×3 key matrix 301 and an expanded key matrix. The expanded key matrix has an additional row/column configuration using a combination to select one or more input ports from the first input ports and the second input ports. The additional row/column configuration may be implemented with keys having at least three input ports from the first and second input ports. For example, a basic key of the 3×3 key matrix 301(e.g., key[0,0] 311) is a two-contact key to connect one first input port to one second input port, and additional keys include three-contact keys (e.g., key[0,3] 313), four-contact keys (e.g., key[0,6] 315), five-contact keys, (e.g., key[3,6] 317), and a six-contact key (key[6,6] 319) according to the number of the first and second input ports connected to the corresponding keys.

Because the key expansion is achieved by the combination of the input ports, the number of the expandable keys is determined according to the number of the first and second input ports. For example, when the electronic device has three first input ports and three second input ports, the keys can be expanded from a three-contact key up to a six-contact key, in addition to a two-contact key of the basic key matrix. A combination that can be selected from the three first input ports and the three second input ports is ₃C₁+₃C₂+₃C₃=3+3+1=7. When each row and column of the key matrix is expanded to 7, a total of 49 basic keys can be obtained. Table 1 below shows the number of the expandable keys according to the number of the input ports.

Specifically, Table 1 shows the number of two-contact keys of the general key matrix, the number of three-contact expansion keys, and the maximum number of the expandable keys according to the number of the input ports of the electronic device.

TABLE 1

| Number of first | | | |
|---|---|---|---|
| input ports/ | Number of | Number of | Maximum |
| Number of second | two-contact | three-contact | number of |
| input ports | expansion key | expansion keys | expandable keys |
| 4/6 | 24 | 76 | 1245 |
| 5/5 | 25 | 100 | 961 |
| 5/6 | 30 | 135 | 2573 |

When the number of the first input ports and the number of the second input ports are 4 and 6, 5 and 5, 5 and 6, respectively, the number of key inputs expandable using the two-contact keys, the three-contact keys, and the maximum number of expandable keys are shown in Table 1. The number of the keys is equal to that of the key input methods. Therefore, it is possible to obtain much more key inputs than the number of the general key matrix (two-contact keys) simply by adding the three-contact keys.

In the case where the keys are expanded using the combination, when the user activates two or more keys almost simultaneously, the electronic device can operate as if one key is activated. In other words, when two or more keys are inputted or closed substantially simultaneously, the electronic device can operate as if one key is inputted or closed which connects input ports to be connected by the two or more closed keys, only if a corresponding expandable key is provided. For example, when key[0,0] 311 and key[0,1] 312 are closed simultaneously, bit values of “Row0” and “Col0” are changed from 0 to 1 by the input of key[0,0] 311 and bit values of “Row0” and “Col0” are changed from 0 to 1 by the input of key[0,1] 312. Consequently, because the bit values of “Row0”, “Col0”, “Col1” are changed from 0 to 1, the electronic device can operate as if key[0,3] connecting “Row0”, “Col0” and “Col1” is closed.

Therefore, it is preferable that the electronic device with the expandable key inputs using the combination of the keys uses an interrupt scheme, instead of a polling scheme. According to the polling scheme, the CPU detects a change of a key state periodically. However, according to the interrupt scheme, the CPU automatically knows the change of the key state immediately when the key state is changed. Because the polling scheme detects the key state periodically, only a finally changed value can be detected even if the key state is changed several times. On the other hand, because the interrupt scheme has a fast response speed, the CPU can know the change of the key state immediately when the key state is changed. Therefore, when the user activates two or more keys simultaneously, the input of the two or more keys can be recognized by detecting the short time difference. In the case of the interrupt scheme, when key[0,0] 311 and key[0,1] 312 are activated simultaneously, the CPU detects the input order of the two keys and performs an operation corresponding to the two key inputs. In this case, if the input of the two keys is designated as one function, that is, if a duplicate key function is used to perform one operation when the two keys are activated simultaneously, the input of the two keys may not be correctly detected according to the input ports included in the duplicate key. The case where the simultaneous input of key[0,0] 311 and key[0,3] 313 is designated as the duplicate key function will be taken as an example. In this case, because key[0,3] 313 includes the input ports of key[0,1] 311 and key[0,1] 312, the CPU cannot determine if key[0,0] 311 and key[0,1] 312 are activated simultaneously, or if key[0,0] 311 and key[0,3] 313 are activated simultaneously, or if key[0,1] 312 and key[0,3] 313 are activated simultaneously. Therefore, when the duplicate key function is designated in the key expansion apparatus of the present invention, it is preferable that the two basic keys are designated as the duplicate key, or it is preferable that a single basic key and an additional key including no input ports connected to the single basic key are designated as the duplicated key.

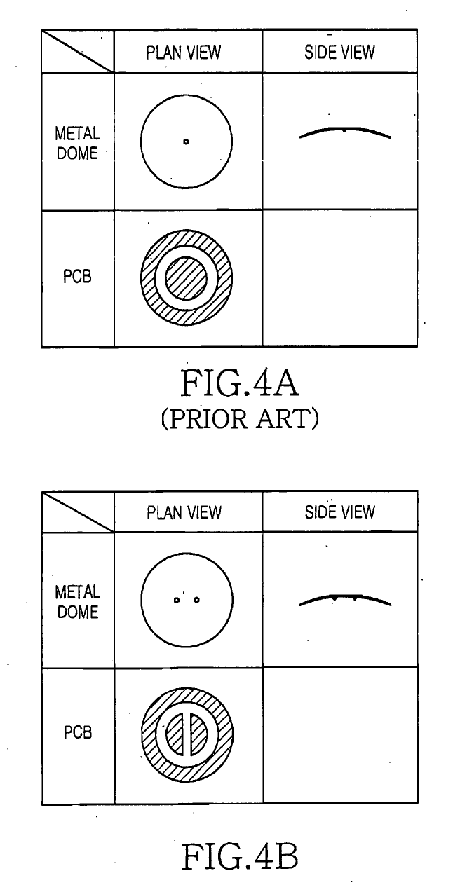

In order to use the three-or-more-contact keys of the key expansion apparatus in the electronic device, metal domes and a printed circuit board (PCB) for the three-or-more-contact keys must be newly designed. The design of the metal domes and the PCB will be described with reference to FIG. 4, taking the three-contact scheme as example. The metal domes are a part that is located under a keyboard of the electronic device. The metal domes detect a key signal inputted from an external device, e.g., a switch, and transfers the detected key signal to the PCB. The PCB transfers the received key signal to a modem of the electronic device.

FIGS. 4A and 4B illustrate metal domes and PCBs of electronic devices according to the related art and the present invention respectively.

Specifically, FIG. 4A illustrates a metal dome and a PCB for the input of a two-contact key according to the related art, and FIG. 4B illustrates a metal dome and a PCB for the input of a three-contact key according to the present invention.

Referring to FIG. 4A, an edge of the metal dome is used as one contact point, and a pointed portion formed at the middle of the metal dome is used as another contact point. Thus, the bit values of the input ports connected to the respective keys are changed by connecting or disconnecting the outermost circle and the innermost circle of the PCB.

Referring to FIG. 4B, the metal dome and the PCB for the input of the three-contact key connecting three input ports must have three different contact points. An edge of the metal dome is used as one contact point, and two pointed portions formed at both sides of the metal dome are used as two other contact points. More than three input ports can have more than three different contact points in a similar way.

As described above, the key expansion apparatus of the present invention can provide the key expansion using the combination of the input ports. Therefore, the key expansion can be easily achieved using a small number of input ports without additional expense.

FIGS. 3, 4A, and 4B schematically show normally open push button keys (or switches) as a preferred embodiment of the present invention.

The same idea as described above can be applied to other embodiments using a touch screen or a touch pad as an input means. In this vase, a key corresponds to an input element.

While the present invention has been shown and described with reference to certain preferred embodiments thereof, it will be understood by those skilled in the art that various changes in forms and details may be made therein without departing from the spirit and scope of the present invention as defined by the appended claims.

What is claimed is:

1. A key expansion apparatus of an electronic device, comprising:
at least one basic key which connects or disconnects one of a plurality of first input ports and one of a plurality of second input ports in order to make a key input; and
at least one additional key which connects or disconnects three or more of the first input ports and the second input ports.

2. The apparatus of claim 1, wherein the at least one additional key is configured using a combination that has at least one of the first input ports and at least one of the second input ports.

3. The apparatus of claim 1, wherein the key input is detected using an interrupt scheme when a key is activated in the electronic device.

4. The apparatus of claim 1, further comprising at least one duplicate key which is designated to two basic keys or to one basic key and an other additional key, wherein an input port of the one basic key being different from an input port of the other additional key.

5. A wireless communication terminal having a key expansion apparatus, comprising:
at least one additional key which connects at least three of first input ports and second input ports.

6. The terminal of claim 5, further comprising at least one basic key which connects one of the first input ports and one of the second input ports in order to make a key input.

7. The terminal of claim 5, wherein the at least one additional key is configured using a combination that has at least one of the first input ports and at least one of the second input ports.

8. The terminal of claim 6, wherein the key input is detected using an interrupt scheme when a key is activated in the wireless communication terminal.

9. The terminal of claim 6, further comprising at least one duplicate key which is designated to two basic keys.

10. The terminal of claim 6, further comprising at least one duplicate key which is designated to one basic key and an other additional key, wherein an input port of the one basic key being different from an input port of the other additional key.

11. An input means for a wireless communication terminal, the input means comprising:
at least one additional input element which connects at least three of first input ports and second input ports.

12. The input means of claim 11, further comprising at least one basic element which connects one of the first input ports and one of the second input ports in order to make an element input.

13. The input means of claim 11, wherein the at least one additional element is configured using a combination that has at least one of the first input ports and at least one of the second input ports.

14. The input means of claim 12, wherein the element input is detected using an interrupt scheme when an element is activated in the wireless communication terminal.

15. The input means of claim 12, further comprising at least one duplicate element which is designated to two basic elements.

16. The input means of claim 12, further comprising at least one duplicate element which is designated to one basic element and an other additional element, wherein an input port of the one basic element being different from an input port of the other additional element.
